(19) United States
(12) Patent Application Publication
(10) Pub. No.: US 2025/0167743 A1
(43) Pub. Date: May 22, 2025

(54) POWER AMPLIFIER

(71) Applicant: Samsung Electro-Mechanics Co., Ltd., Suwon-si (KR)

(72) Inventors: Kyujin CHOI, Suwon-si (KR); Jaehyouck CHOI, Suwon-si (KR); Ingeun YU, Suwon-si (KR); Yoshiyuki TONAMI, Suwon-si (KR); Kyung Hee HONG, Suwon-si (KR)

(73) Assignee: Samsung Electro-Mechanics Co., Ltd., Suwon-si (KR)

(21) Appl. No.: 18/668,952

(22) Filed: May 20, 2024

(30) Foreign Application Priority Data
Nov. 20, 2023 (KR) 10-2023-0161486

(51) Int. Cl. H03F 3/24; H03F 1/02

(52) U.S. Cl. CPC H03F 3/245; H03F 1/0211; H03F 2200/451

(57) ABSTRACT

A power amplifier includes a first power transistor configured to amplify a first input Radio Frequency (RF) signal, and output a first output RF signal; a first bias circuit configured to operate in a first communication mode, and comprising a first transistor configured to supply a first bias current to the first power transistor; and a second bias circuit configured to operate in a second communication mode, and comprising a second transistor configured to supply a second bias current to the first power transistor.

### CROSS-REFERENCE TO RELATED APPLICATIONS

This application claims the benefit under 35 USC 119 (a) of Korean Patent Application No. 10-2023-0161486 filed on Nov. 20, 2023, in the Korean Intellectual Property Office, the entire disclosure of which is incorporated herein by reference for all purposes.

### BACKGROUND

### (a) Field

The following description relates to a power amplifier.

### (b) Description of the Background

Wireless communication systems employ a variety of digital modulation/demodulation schemes as communication standards evolve. Conventional Code Division Multiple Access (CDMA) communication systems use the Quadrature Phase Shift Keying (QPSK) scheme, and Wireless LANs that follow IEEE's communication standards use the Orthogonal Frequency Division Multiplexing (OFDM) scheme. The most recent 3GPP standards, Long Term Evolution (LTE) and LTE-Advanced, utilize QPSK, Quadrature Amplitude Modulation (QAM), and OFDM schemes.

A transmitting terminal of a wireless communication system includes a Front End Module (FEM). More recently, there has been a trend toward a single FEM supporting multiple communication modes. A power amplifier mounted in the FEM is also implemented in a single Integrated Circuit (IC) core, which may be desired to support multiple communication modes. When a power amplifier implemented in a single IC core supports multiple communication modes, it may be desired that performance indexes, such as linearity and efficiency, are optimized for each communication mode.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a power amplifier includes a first power transistor configured to amplify a first input Radio Frequency (RF) signal, and output a first output RF signal; a first bias circuit configured to operate in a first communication mode, and comprising a first transistor configured to supply a first bias current to the first power transistor; and a second bias circuit configured to operate in a second communication mode, and comprising a second transistor configured to supply a second bias current to the first power transistor.

The power amplifier may further include a first linearization circuit connected between a terminal to which the first input RF signal is input and the first bias circuit, and which, in the first communication mode, is configured to couple a portion of the first input RF signal to an output of the first bias circuit; and a second linearization circuit connected between the terminal to which the first input RF signal is input and the second bias circuit, and which, in the second communication mode, is configured to couple a portion of the first input RF signal to an output of the second bias circuit.

The first transistor may include a first terminal configured to supply the first bias current to the first power transistor. The second transistor may include a first terminal configured to supply the second bias current to the first power transistor. The first linearization circuit may be configured to couple, in the first communication mode, a portion of the first input RF signal to an output of the first terminal of the first transistor. The second linearization circuit may be configured to couple, in the second communication mode, a portion of the first input RF signal to an output of the first terminal of the second transistor.

The first linearization circuit may include a first capacitor connected between the terminal to which the first input RF signal is input and the first terminal of the first transistor. The second linearization circuit may include a second capacitor connected between the terminal to which the first input RF signal is input and the first terminal of the second transistor.

The first linearization circuit may further include a first resistor connected in series with the first capacitor between the terminal to which the first input RF signal is input and the first terminal of the first transistor. The second linearization circuit may further include a second resistor connected in series with the second capacitor between the terminal to which the first input RF signal is input and the first terminal of the second transistor.

The first transistor may include a first terminal configured to supply the first bias current to the first power transistor. The second transistor may include a first terminal configured to supply the second bias current to the first power transistor. The power amplifier may further include a first capacitor comprising a first terminal connected to a terminal to which the first input RF signal is input, a first resistor connected between a second terminal of the first capacitor and the first terminal of the first transistor, and a second resistor connected between the second terminal of the first capacitor and the first terminal of the second transistor.

The first capacitor and the first resistor may be configured to couple a portion of the first input RF signal to an output of the first terminal of the first transistor in the first communication mode. The first capacitor and the second resistor may be configured to couple a portion of the first input RF signal to an output of the first terminal of the second transistor in the second communication mode.

The power amplifier may further include a first resistor connected between the first terminal of the first transistor and an input terminal of the power transistor, and a second resistor connected between the first terminal of the second transistor and the input terminal of the power transistor.

The first terminal of the first transistor may be an emitter of the first transistor, and the first terminal of the second transistor may be an emitter of the second transistor.

The first communication mode may be a 2G communication mode, and the second communication mode may be a 4G communication mode or a 5G communication mode.

The power amplifier may further include a second power transistor configured to amplify a second input RF signal and output a second output RF signal; and a third bias circuit, configured to operate in the first communication mode and the second communication mode, including a third transistor configured to supply a third bias current to the second power transistor. The first input RF signal may correspond to the second output RF signal.

The power amplifier may further include a third linearization circuit connected between a terminal to which the second input RF signal is input and the third bias circuit, and which, in the first communication mode and the second communication mode, configured to couple a portion of the second input RF signal to an output of the third bias circuit.

The third transistor may include a first terminal configured to supply the third bias current to the second power transistor. The third linearization circuit may include a capacitor connected between the terminal to which the second input RF signal is input and the first terminal of the third transistor.

The third linearization circuit may further include a resistor connected in series with the capacitor between the terminal to which the second input RF signal is input and the first terminal of the third transistor.

In another general aspect, a power amplifier includes a first power transistor configured to amplify a first input Radio Frequency (RF) signal, and output a first output RF signal; a first transistor configured to operate in a first communication mode and a second communication mode, and including a first terminal configured to supply a first bias current to the first power transistor; a second power transistor configured to amplify a second input RF signal corresponding to the first output RF signal, and output a second output RF signal; a second transistor configured to operate in the first communication mode and comprising a first terminal configured to supply a second bias current to the second power transistor; and a third transistor configured to operate in the second communication mode and including a first terminal configured to supply a third bias current to the second power transistor.

The power amplifier may further include a first linearization circuit connected between a terminal to which the first input RF signal is input and the first terminal of the first transistor, and configured to couple, in the first communication mode and the second communication mode, a portion of the first input RF signal to an output of the first terminal of the first transistor; a second linearization circuit connected between a terminal to which the second input RF signal is input and the first terminal of the second transistor, and configured to couple, in the first communication mode, a portion of the second input RF signal to an output of the first terminal of the second transistor; and a third linearization circuit connected between the terminal to which the second input RF signal is input and the first terminal of the third transistor, and configured to couple, in the second communication mode, a portion of the second input RF signal to an output of the first terminal of the third transistor.

The first linearization circuit may include a first capacitor and a first resistor connected in series between the terminal to which the first input RF signal is input and the first terminal of the first transistor. The second linearization circuit may include a second capacitor and a second resistor connected in series between the terminal to which the second input RF signal is input and the first terminal of the second transistor. The third linearization circuit may include a third capacitor and a third resistor connected in series between the terminal to which the second input RF signal is input and the first terminal of the third transistor.

The power amplifier may further include a first capacitor including a first terminal connected to a terminal to which the second input RF signal is input, a first resistor connected between a second terminal of the first capacitor and the first terminal of the second transistor, and a second resistor connected between the second terminal of the first capacitor and the first terminal of the third transistor.

The first capacitor and the first resistor may be configured to couple a portion of the second input RF signal to an output of the first terminal of the second transistor in the first communication mode. The first capacitor and the second resistor may be configured to couple a portion of the second input RF signal to an output of the first terminal of the third transistor in the second communication mode.

The first terminal of the first transistor may be an emitter of the first transistor, the first terminal of the second transistor may be an emitter of the second transistor, and the first terminal of the third transistor may be an emitter of the third transistor.

Other features and aspects will be apparent from the following detailed description, the drawings, and the claims.

### BRIEF DESCRIPTION OF DRAWINGS

FIG. 1 is a diagram illustrating a power amplifier 1000A according to an embodiment.

FIG. 2 is a circuit diagram illustrating one example of a bias circuit 200_1 of FIG. 1.

FIG. 3 is a circuit diagram illustrating one example of a bias circuit 200_21 of FIG. 1.

FIG. 4 is a circuit diagram illustrating one example of a bias circuit 200_22 of FIG. 1.

FIG. 5 is a diagram illustrating a power amplifier 1000B according to another embodiment.

FIG. 6 is a diagram illustrating one example of a linearization circuit 400_1 of FIG. 5.

FIG. 7 is a diagram illustrating one example of a linearization circuit 400_21 of FIG. 5.

FIG. 8 is a diagram illustrating one example of a linearization circuit 400_22 of FIG. 5.

FIG. 9 is a diagram illustrating one example of a linearization circuit 400_2.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, RF signals may be in the form of any other wireless and wired protocols designated as Wi-Fi (the IEEE 802.11 family and the like), WiMAX (the IEEE 802.16 family and the like), IEEE 802.20, Long Term Evolution (LTE), Ev-DO, HSPA+, HSDPA+, HSUPA+, EDGE, GSM, GPS, GPRS, CDMA, TDMA, DECT, Bluetooth, 3G, 4G, 5G, and thereafter, but are not limited thereto.

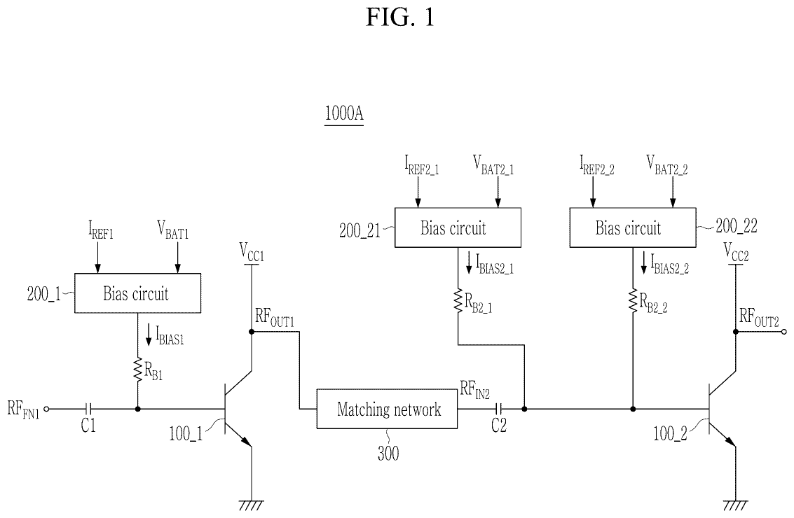

FIG. 1 is a diagram illustrating a power amplifier 1000A according to an embodiment.

As illustrated in FIG. 1, a power amplifier 1000A, according to an embodiment, may include a power transistor 100_1, a bias circuit 200_1, a capacitor C1, a power transistor 100_2, a bias circuit 200_21, a bias circuit 200_22, a capacitor C2, and a matching network 300.

The power transistor 100_1, the bias circuit 200_1, and the capacitor C1 may configure a first stage amplifier, and the power transistor 100_2, the bias circuit 200_21, the bias circuit 200_22, and the capacitor C2 may configure a second stage amplifier. The first stage amplifier may be a driver amplifier, and the second stage amplifier may be a power amplifier.

The power transistor 100_1 may include an input terminal and an output terminal. The input terminal may be a base of the power transistor 100_1, and the output terminal may be a collector of the power transistor 100_1. The power transistor 100_1 may amplify power for an input RF signal RF_{IN1} input to the input terminal (for example, the base) and output the amplified power to the output terminal (for example, the collector). In FIG. 1, the RF signal output from the output terminal of the power transistor 100_1 is indicated as “output RF signal RF_{OUT1}”. The emitter of the power transistor 100_1 may be connected to ground, and although not illustrated in FIG. 1, a resistor may be further connected between the emitter of the power transistor 100_1 and ground. The collector of the power transistor 100_1 may be connected to a power supply voltage V_{CC1}, and the power transistor 100_1 may be operated by the power supply voltage V_{CC1}. Although not illustrated in FIG. 1, an inductor performing an RF choke function may be connected between the collector of the power transistor 100_1 and the power supply voltage V_{CC1}.

The power transistor 100_1 may be implemented with various transistors, such as a Heterojunction Bipolar Transistor (HBT), a Bipolar Junction Transistor (BJT), and an Insulated Gate Bipolar Transistor (IGBT). In FIG. 1, the power transistor 100_1 is represented as the n-type, but may be replaced with the p-type.

The capacitor C1 is a coupling capacitor and may be connected to the input terminal (for example, the base) of the power transistor 100_1. That is, the input RF signal RF_{IN1} may be input to one end of the capacitor C1, and the other end of the capacitor C1 may be connected to the base of the power transistor 100_1. The capacitor C1 may perform the function of blocking the Direct Current (DC) component from the input RF signal RF_{IN1}.

The bias circuit 200_1 may receive a reference current I_{REF1} and a power supply voltage V_{BAT1} from an external source. The bias circuit 200_1 may generate a bias current I_{BIAS1} desired by the power transistor 100_1 by using the reference current I_{REF1} and the power supply voltage V_{BAT1}. The bias current I_{BIAS1} is supplied to the input terminal (for example, the base) of the power transistor 100_1, and a bias level (bias point) of the power transistor 100_1 may be set by the bias current I_{BIAS1}. The power supply voltage V_{BAT1} may be supplied from a battery.

The bias circuit 200_1 may generate a bias current I_{BIAS1} regardless of the communication mode (for example, in a first communication mode and a second communication mode), and supply the generated bias current I_{BIAS1} to the input terminal (for example, the base) of the power transistor 100_1 through the resistor R_{B1}. The reference current I_{REF1} may be generated regardless of the communication mode and supplied to the bias circuit 200_1, and the bias circuit 200_1 may generate the bias current I_{BIAS1} regardless of the communication mode. Here, the communication mode may include a first communication mode and a second communication mode. For example, the first communication mode may indicate a case where the input RF signal RF_{IN1} is a 2G communication mode. For example, the second communication mode may indicate a case where the input RF signal RF_{IN1} is a 4G communication mode (LTE communication mode) or a 5G communication mode (New Radio (NR) communication mode). That is, the bias circuit 200_1 may bias the power transistor 100_1 in the first communication mode and the second communication mode.

The power transistor 100_2 may include an input terminal and an output terminal. The input terminal may be a base of the power transistor 100_2, and the output terminal may be a collector of the power transistor 100_2. The power transistor 100_2 may amplify the power of an input RF signal RF_{IN2} input to the input terminal (for example, the base) and then output the amplified power to the output terminal (for example, the collector). In FIG. 1, the RF signal output from the output terminal of the power transistor 100_2 is indicated as ‘output RF signal RF_{OUT2}’. The emitter of power transistor 100_2 may be connected to ground, and although not illustrated in FIG. 1, a resistor may be further connected between the emitter of power transistor 100_2 and ground. Additionally, the collector of the power transistor 100_2 may be connected to a power supply voltage V_{cc2}, and the power transistor 100_2 may be operated by the power supply voltage V_{CC2}. Although not illustrated in FIG. 1, an inductor that performs an RF choke function may be connected between the collector of the power transistor 100_2 and the power supply voltage V_{CC2}. The power supply voltage V_{CC2} may be the same as or different from the power supply voltage V_{CC1}.

The power transistor 100_2 may be implemented with various transistors, such as a Heterojunction Bipolar Transistor (HBT), a Bipolar Junction Transistor (BJT), and an Insulated Gate Bipolar Transistor (IGBT). In FIG. 1, the power transistor 100_2 is represented as the n-type, but may be replaced with the p-type.

The matching network 300 may be connected between the output terminal (for example, the collector) of the power transistor 100_1 and the input terminal (for example, the base) of the power transistor 100_2. The matching network 300 performs impedance matching between the output RF signal RF_{OUT1} and the input terminal of the power transistor 100_2. The matching network 300 may be implemented as a combination of at least one of a resistor, an inductor, and a capacitor.

The capacitor C2 is a coupling capacitor and may be connected between the matching network 300 and the input terminal (for example, the base) of the power transistor 100_2. The output RF signal RF_{OUT1} may be input to the input terminal (for example, the base) of the power transistor 100_2 through the matching network 300 and the capacitor C2. From the perspective of the Radio Frequency (RF) signal, the output RF signal RF_{OUT1} of the first stage amplifier may be the input RF signal RF_{IN2} of the second stage amplifier. The capacitor C2 may perform the function of blocking the Direct Current (DC) component from the input RF signal RF_{IN2}.

The bias circuit 200_21 may receive a reference current I_{REF2_1} and a power supply voltage V_{BAT2_1} from an external source. The bias circuit 200_21 may generate a bias current I_{BIAS2_1} desired by the power transistor 100_2 by using the reference current I_{REF2_1} and the power supply voltage V_{BAT2_1}. The bias current I_{BIAS2_1} is supplied to the input terminal (for example, the base) of the power transistor 100_2, and a bias level (bias point) of the power transistor 100_2 may be set by the bias current I_{BIAS2_1}. The power supply voltage V_{BAT2_1} may be supplied from a battery and may be the same power voltage as the power supply voltage V_{BAT1}.

The bias circuit 200_21, according to the embodiment, may generate the bias current I_{BIAS2_1} only in the first communication mode, and supply the generated bias current I_{BIAS2_1} to the input terminal (for example, the base) of the power transistor 100_2 through the resistor RB2_1. The reference current I_{REF2_1} may be generated in the first communication mode and supplied to the bias circuit 200_21. The bias circuit 200_21 may generate the bias current I_{BIAS2_1} in the first communication mode. That is, the bias circuit 200_21 may bias the power transistor 100_2 in the first communication mode.

The bias circuit 200_22 may receive a reference current I_{REF2_2} and a power supply voltage V_{BAT2_2} from an external source. The bias circuit 200_22 may generate a bias current I_{BIAS2_2} desired by the power transistor 100_2 using the reference current I_{REF2_2} and the power supply voltage V_{BAT2_2}. The bias current I_{BIAS2_2} may be supplied to the input terminal (for example, the base) of the power transistor 100_2, and a bias level (bias point) of the power transistor 100_2 may be set by the bias current I_{BIAS2_2}. The power supply voltage V_{BAT2_2} may be supplied from a battery and may be the same as the power supply voltage V_{BAT1} or the power supply voltage V_{BAT2_1}.

The bias circuit 200_21, according to the embodiment, may generate the bias current I_{BIAS2_1} only in the first communication mode, and the generated bias current I_{BIAS2_1} may be supplied to the input terminal (for example, the base) of the power transistor 100_2 via the resistor RB2_1. The reference current I_{REF2_1} may be generated in the first communication mode and supplied to the bias circuit 200_21, and the bias circuit 200_21 may generate the bias current I_{BIAS2_1} in the first communication mode. That is, the bias circuit 200_21 may bias the power transistor 100_2 in the first communication mode.

The bias circuit 200_22 may receive the reference current I_{REF2_2} and the power supply voltage V_{BAT2_2} from an external source. The bias circuit 200_22 may generate the bias current I_{BIAS2_2} desired by the power transistor 100_2 by using the reference current I_{REF2_2} and the power supply voltage V_{BAT2_2}. The bias current I_{BIAS2_2} may be supplied to the input terminal (for example, the base) of the power transistor 100_2, and the power transistor 100_2 may have a bias level (bias point) set by the bias current I_{BIAS2_2}. The power supply voltage V_{BAT2_2} may be supplied from a battery and may be the same power supply voltage as the power supply voltage V_{BAT1} or the power supply voltage V_{BAT2_1}.

The bias circuit 200_22, according to the embodiment, may generate the bias current I_{BIAS2_2} only in the second communication mode, and the generated bias current I_{BIAS2_2} may be supplied to the input terminal (for example, the base) of the power transistor 100_2 via the resistor R_{B2_2}. The reference current I_{REF2_2} may be generated in the second communication mode and supplied to the bias circuit 200_22, and the bias circuit 200_22 may generate the bias current I_{BIAS2_2} in the second communication mode. That is, the bias circuit 200_22 may bias the power transistor 100_2 in the second communication mode.

The power amplifier 1000A, according to the embodiment, may further include a resistor R_{B1}, a resistor R_{B2_1}, and a resistor R_{B2_2}.

The resistor R_{B1} may be connected between the bias circuit 200_1 and the input terminal (for example, the base) of the power transistor 100_1. Here, the resistor R_{B1} may be a ballast resistor to improve the heat dissipation characteristics of the power amplifier 1000A. Although FIG. 1 illustrates the resistor R_{B1} as a separate configuration from the bias circuit 200_1, the resistor R_{B1} may be included in the bias circuit 200_1.

The resistor R_{B2_1} may be connected between the bias circuit 200_21 and the input terminal (for example, the base) of the power transistor 100_2. Here, the resistor R_{B2_1} may be a ballast resistor to improve the heat dissipation characteristics of the power amplifier 1000A. Although FIG. 1 illustrates the resistor R_{B2_1} as a separate configuration from the bias circuit 200_21, the resistor R_{B2_1} may be included in the bias circuit 200_21.

The resistor R_{B2_2} may be connected between the bias circuit 200_22 and the input terminal (for example, the base) of the power transistor 100_2. Here, the resistor R_{B2_2} may be a ballast resistor to improve the heat dissipation characteristics of the power amplifier 1000A. Although FIG. 1 illustrates the resistor R_{B2_2} as a separate configuration from the bias circuit 200_22, the resistor R_{B2_2} may be included in the bias circuit 200_22.

The power amplifier 1000A, according to the embodiment, may be designed with one core to cover the first communication mode and the second communication mode simultaneously. The bias circuit 200_1 may be commonly used in both the first communication mode and the second communication mode. Further, the bias circuit 200_21 may be operated only in the first communication mode, and the bias circuit 200_22 may be operated only in the second communication mode. Here, since the bias circuit 200_21 and the bias circuit 200_22 are selectively operated according to the communication mode, each of the bias circuit 200_21 and the bias circuit 200_22 may be designed to be optimized according to the communication mode. The optimized bias circuit 200_21 and bias circuit 200_22 allow the power amplifier 1000A, according to the embodiment, to satisfy performance metrics (for example, linearity and efficiency) desired by the various communication modes while supporting multiple communication modes simultaneously.

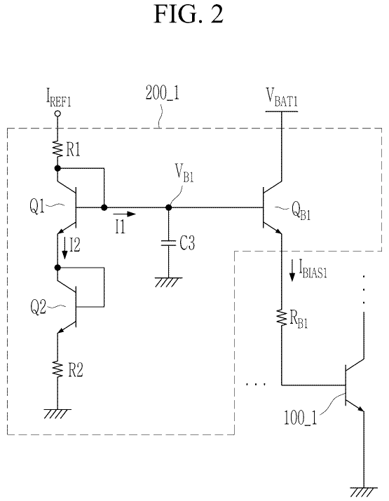

FIG. 2 is a circuit diagram illustrating one example of the bias circuit 200_1 of FIG. 1.

As illustrated in FIG. 2, the bias circuit 200_1 may include a transistor Q1, a transistor Q2, a transistor QB1, a resistor R1, a resistor R2, and a capacitor C3.

The transistors Q1, Q2, and QB1 may be implemented with various transistors, such as a Heterojunction Bipolar Transistor (HBT), a Bipolar Junction Transistor (BJT), and an Insulated Gate Bipolar Transistor (IGBT). Further, in FIG. 2, the transistors Q1, Q2, and QB1 are illustrated as n-type, but may be replaced by p-type. On the other hand, the bases of the transistors Q1, Q2, and QB1 serve as control terminals, thereby being used as the term “control terminal.” A collector of each of the transistors Q1, Q2, and QB1 is one terminal of the transistor, thereby being used as the term “first terminal or second terminal.” An emitter of each of the transistors Q1, Q2, and QB1 is one terminal of the transistor, thereby being used as the term “second terminal or first terminal.”

The base and the collector of the transistor Q1 may be connected to each other, and the collector of the transistor Q1 may be supplied with the reference current I_{REF1} through the resistor R1. Here, the transistor Q1 may have a diode connection structure. The transistor Q1 serves to sink a current I2 from the reference current I_{REF1}. Here, the reference current I_{REF1} may be generated by a current source and may be supplied to the bias circuit 200_1 regardless of the communication mode (for example, in the first and second communication modes).

The base and the collector of the transistor Q2 may be connected to each other, and the collector of the transistor Q2 may be connected to the emitter of the transistor Q1. The transistor Q2 may have a diode connection structure, and the emitter of the transistor Q2 may be connected to ground via the resistor R2.

The collector of the transistor QB1 may be supplied with the power supply voltage V_{BAT1}, and the base of the transistor QB1 may be connected to the base of the transistor Q1. In FIG. 2, the base voltage of the transistor QB1 is indicated by “V_{B1}”. The emitter of the transistor QB1 may be connected to the input terminal (for example, the base) of the power transistor 100_1 via the resistor R_{B1}. The current flowing in the emitter of the transistor QB1 is the bias current I_{BIAS1} described in FIG. 1 above. The collector of the transistor QB1 is the terminal that is supplied with the power supply voltage V_{BAT1}, and the emitter of the transistor QB1 is the terminal that supplies the bias current I_{BIAS1}_A to the power transistor 100_1.

The capacitor C3 may be connected between the base of the transistor QB1 and ground. The capacitor C3 may play a role in stabilizing the base voltage V_{B1} of the transistor QB1 and reducing the impedance of the transistor QB1 at the same time.

The reference current I_{REF1} is divided into a current I1 and a current I2, and the current I1 may be input to the base of the transistor QB1. Accordingly, the bias current I_{BIAS1} may be determined in response to the current I1. And, the bias current I_{BIAS1} may be determined in response to the base voltage V_{B1} of the transistor QB1. As one example, when the base voltage V_{B1} of the transistor QB1 is increased, the bias current I_{BIAS1} may be increased.

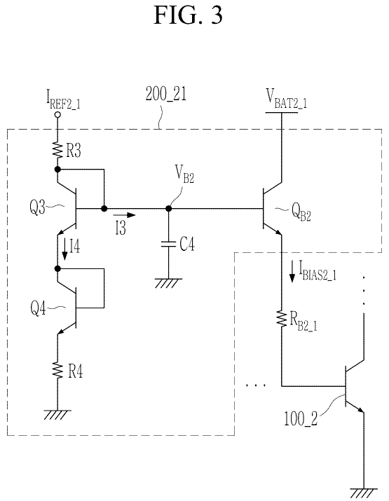

FIG. 3 is a circuit diagram illustrating one example of the bias circuit 200_21 of FIG. 1.

As illustrated in FIG. 3, the bias circuit 200_21 may include a transistor Q3, a transistor Q4, a transistor QB2, a resistor R3, a resistor R4, and a capacitor C4.

The transistors Q3, Q4, and QB2 may be implemented with various transistors, such as a Heterojunction Bipolar Transistor (HBT), a Bipolar Junction Transistor (BJT), and an Insulated Gate Bipolar Transistor (IGBT). Further, in FIG. 3, the transistors Q3, Q4, and QB2 are illustrated as n-type, but may be replaced by p-type. On the other hand, the bases of the transistors Q3, Q4, and QB2 serve as control terminals, thereby using the term “control terminal”. A collector of each of the transistors Q3, Q4, and QB2 is one terminal of the transistor, thereby being used as the term “first terminal or second terminal.” An emitter of each of the transistors Q3, Q4, and QB2 is one terminal of the transistor, thereby being used as the term “second terminal or first terminal.”

The base and the collector of the transistor Q3 may be connected to each other, and the collector of the transistor Q3 may be supplied with the reference current I_{REF2_1} through the resistor R3. Here, the transistor Q3 may have a diode connection structure. The transistor Q3 serves to sink a current I4 from the reference current I_{REF2_1}. Here, the reference current I_{REF2_1} may be generated by a current source and supplied to the bias circuit 200_21 in the first communication mode.

The base and the collector of the transistor Q4 may be connected to each other, and the collector of the transistor Q4 may be connected to the emitter of the transistor Q3. The transistor Q4 may have a diode connection structure, and the emitter of the transistor Q4 may be connected to ground via the resistor R4.

The collector of the transistor QB2 may be supplied with the power supply voltage V_{BAT2_1}, and the base of the transistor QB2 may be connected to the base of the transistor Q3. In FIG. 3, the base voltage of the transistor QB2 is indicated by “V_{B2}”. The emitter of the transistor QB2 may be connected to the input terminal (for example, the base) of the power transistor 100_2 via the resistor R_{B2_1}. The current flowing in the emitter of the transistor QB2 is the bias current I_{BIAS2_1} described in FIG. 1 above. The collector of the transistor QB2 is the terminal that is supplied with the power supply voltage V_{BAT2_1}, and the emitter of the transistor QB2 is the terminal that supplies the bias current I_{BIAS2_1} to the power transistor 100_2.

The capacitor C4 may be connected between the base of the transistor QB2 and ground. The capacitor C4 may play a role in stabilizing the base voltage V_{B2} of the transistor QB2 and reducing the impedance of the transistor QB2 at the same time.

The reference current I_{REF2_1} is divided into a current I3 and a current I4, and the current I3 may be input to the base of the transistor QB2. Accordingly, the bias current I_{BIAS2_1} may be determined in response to the current I3. And, the bias current I_{BIAS2_1} may be determined in response to the base voltage V_{B2} of the transistor QB2. As one example, when the base voltage V_{B2} of the transistor QB2 is increased, the bias current I_{BIAS2_1} may increase.

As described above, the bias circuit 200_21 may operate only in the first communication mode to generate the bias current I_{BIAS2_1}. Accordingly, the bias circuit 200_21 of FIG. 3 may be designed to be suitable for the first communication mode. For example, in FIG. 3, each of the reference current I_{REF2_1}, the resistor R3, the resistor R4, the capacitor C4, the transistor Q3, the transistor Q4, and the transistor QB2 may have a design value suitable for the first communication mode.

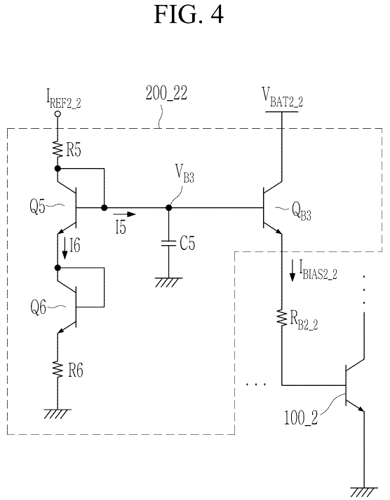

FIG. 4 is a circuit diagram illustrating one example of the bias circuit 200_22 of FIG. 1.

As illustrated in FIG. 4, the bias circuit 200_22 may include a transistor Q5, a transistor Q6, a transistor QB3, a resistor R5, a resistor R6, and a capacitor C5.

The transistors Q5, Q6, and QB3 may be implemented with various transistors, such as a Heterojunction Bipolar Transistor (HBT), a Bipolar Junction Transistor (BJT), and an Insulated Gate Bipolar Transistor (IGBT). Further, in FIG. 4, the transistors Q5, Q6, and QB3 are illustrated as n-type, but may be replaced by p-type. On the other hand, the bases of the transistors Q5, Q6, and QB3 serve as control terminals, thereby being used as the term “control terminal.” A collector of each of the transistors Q5, Q6, and QB3 is one terminal of the transistor, thereby being used as the term “first terminal or second terminal.” An emitter of each of the transistors Q5, Q6, and QB3 is one terminal of the transistor, thereby being used as the term “second terminal or first terminal.”

The base and the collector of the transistor Q5 may be connected to each other, and the collector of the transistor Q5 may be supplied with the reference current I_{REF2_2} through the resistor R5. Here, the transistor Q5 may have a diode connection structure. The transistor Q5 serves to sink a current I6 from the reference current I_{REF2_2}. Here, the reference current I_{REF2_2} may be generated by a current source and supplied to the bias circuit 200_22 in the second communication mode.

The base and the collector of the transistor Q6 may be connected to each other, and the collector of the transistor Q6 may be connected to the emitter of the transistor Q5. The transistor Q6 may have a diode connection structure, and the emitter of the transistor Q6 may be connected to ground via the resistor R6.

The collector of the transistor QB3 may be supplied with the power supply voltage V_{BAT2_2}, and the base of the transistor QB3 may be connected to the base of the transistor Q5. In FIG. 4, the base voltage of the transistor QB3 is indicated by “V_{B3}”. The emitter of the transistor QB3 may be connected to the input terminal (for example, the base) of the power transistor 100_2 via the resistor R_{B2_2}. The current flowing in the emitter of the transistor QB3 is the bias current I_{BIAS2_2} described in FIG. 1 above. The collector of the transistor QB3 is the terminal that is supplied with the power supply voltage V_{BAT2_2}, and the emitter of the transistor QB3 is the terminal that supplies the bias current I_{BIAS2_2} to the power transistor 100_2.

The capacitor C5 may be connected between the base of the transistor QB3 and ground. The capacitor C5 may play a role in stabilizing the base voltage V_{B3} of the transistor QB3 and reducing the impedance of the transistor QB3 simultaneously.

The reference current I_{REF2_2} is divided into a current I5 and a current I6, and the current I5 may be input to the base of the transistor QB3. Accordingly, the bias current I_{BIAS2_2} may be determined in response to the current I5. Further, the bias current I_{BIAS2_2} may be determined in response to the base voltage V_{B3} of the transistor QB3. As one example, when the base voltage V_{B3} of the transistor QB3 is increased, the bias current I_{BIAS2_2} may increase.

As described above, the bias circuit 200_22 may operate only in the second communication mode to generate the bias current I_{BIAS2_2}. Accordingly, the bias circuit 200_21 of FIG. 4 may be designed to be suitable for the second communication mode. For example, in FIG. 4, each of the reference current I_{REF2_2}, the resistor R5, the resistor R6, the capacitor C5, the transistor Q5, the transistor Q6, and the transistor QB3 may have a design value suitable for the second communication mode.

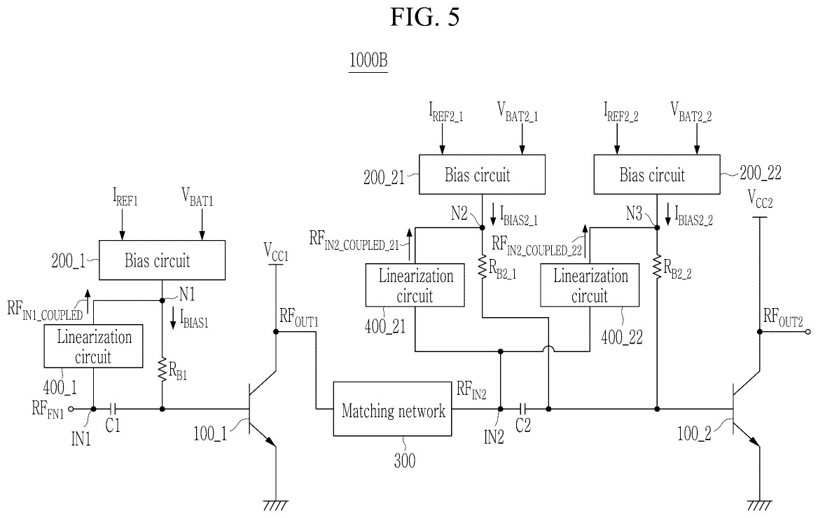

FIG. 5 is a diagram illustrating a power amplifier 1000B according to another embodiment.

The power amplifier 1000B of FIG. 5 may be similar to the power amplifier 1000A of FIG. 1 except for the addition of a linearization circuit 400_1, a linearization circuit 400_21, and a linearization circuit 400_22. As a result, redundant descriptions may be omitted.

In FIG. 5, the terminal where the input RF signal RF_{IN1} is input is indicated by ‘IN1’, and the terminal where the input RF signal RF_{IN2} is input is indicated by ‘IN2’. In FIG. 5, a node where the bias circuit 200_1 and the resistor R_{B1} are connected to each other is indicated by “N1”, a node where the bias circuit 200_21 and the resistor R_{B2_1} are connected to each other is indicated by “N2”, and a node where the bias circuit 200_22 and the resistor R_{B2_2} are connected to each other is indicated by “N3”.

The linearization circuit 400_1 may be connected between the terminal IN1 and the node N1. The linearization circuit 400_1 may improve the linearity of the power transistor 100_1 regardless of the communication mode (for example, in the first communication mode and the second communication mode). As the power of the output RF signal RF_{OUT1} increases, a base voltage droop of the power transistor 100_1 may occur. The linearization circuit 400_1 may compensate for the base voltage droop of the power transistor 100_1 by using the input RF signal RF_{IN1}.

As the power of the output RF signal RF_{OUT1} increases, the bias current I_{BIAS1} may also increase. The increase in the bias current I_{BIAS1} causes the voltage difference between the two ends of the resistor R_{B1} to increase, which may reduce the base voltage of the power transistor 100_1. The linearization circuit 400_1 may compensate for the base voltage droop of the power transistor 100_1. The linearization circuit 400_1 may couple a portion of the signal of the input RF signal RF_{IN1} and output the coupled signal to the node N1. Hereinafter, the input RF signal RF_{IN1} that is coupled by the linearization circuit 400_1 is referred to as the “coupled input RF signal RF_{IN1_COUPLED}”. The specific configuration and operation of the linearization circuit 400_1 will be described in more detail below.

The coupled input RF signal RF_{IN1_COUPLED} is input to the emitter (see FIG. 2) of the transistor QB1 of the bias circuit 200_1, which may cause the bias current I_{BIAS1} to increase. By increasing the bias current I_{BIAS1}, the base voltage droop of the power transistor 100_1 may be compensated for. That is, the linearization circuit 400_1 may compensate for the base voltage droop of the power transistor 100_1, thereby improving linearity. As described above in FIG. 1, the bias circuit 200_1 generates the bias current I_{BIAS1} regardless of the communication mode, so the linearization circuit 400_1 may also compensate for the base voltage droop of the power transistor 100_1 regardless of the communication mode.

The linearization circuit 400_21 may be connected between the terminal IN2 and the node N2. The linearization circuit 400_21 may improve the linearity of the power transistor 100_2 in the first communication mode. As the power of the output RF signal RF_{OUT2} increases, a base voltage droop of the power transistor 100_2 may occur. The linearization circuit 400_21 may compensate for the base voltage droop of the power transistor 100_2 by using the input RF signal RF_{IN2}.

As the power of the output RF signal RF_{OUT2} increases, the bias current I_{BIAS2_1} may also increase. The increase in the bias current I_{BIAS2_1} causes the voltage difference between the two ends of the resistor R_{B2_1} to increase, which may reduce the base voltage of the power transistor 100_2. The linearization circuit 400_21 may compensate for the base voltage droop of the power transistor 100_2. The linearization circuit 400_21 may couple a portion of the signal of the input RF signal RF_{IN2} and output the coupled signal to the node N2. Hereinafter, the input RF signal RF_{IN2} that is coupled by the linearization circuit 400_21 is referred to as the “coupled input RF signal RF_{IN2_COUPLED_21}”. The specific configuration and operation of the linearization circuit 400_21 will be described in more detail below.

The coupled input RF signal RF_{IN2_COUPLED_21} is input to the emitter (see FIG. 3) of the transistor QB2 of the bias circuit 200_21, which may cause the bias current I_{BIAS2_1} to increase. By increasing the bias current I_{BIAS2_1}, the base voltage droop of the power transistor 100_2 may be compensated for. That is, the linearization circuit 400_21 may compensate for the base voltage droop of the power transistor 100_2, thereby improving linearity. As described above in FIG. 1, the bias circuit 200_21 generates the bias current I_{BIAS2_1} in the first communication mode, so the linearization circuit 400_21 may also compensate for the base voltage droop of the power transistor 100_2 in the first communication mode.

The linearization circuit 400_22 may be connected between the terminal IN2 and the node N3. The linearization circuit 400_22 may improve the linearity of the power transistor 100_2 in the second communication mode. As the power of the output RF signal RF_{OUT2} increases, a base voltage droop of the power transistor 100_2 may occur. The linearization circuit 400_22 may compensate for the base voltage droop of the power transistor 100_2 by using the input RF signal RF_{IN2}.

As the power of the output RF signal RF_{OUT2} increases, the bias current I_{BIAS2_2} may also increase. The increase in the bias current I_{BIAS2_2} causes the voltage difference between the two ends of the resistor R_{B2_2} to increase, which may reduce the base voltage of the power transistor 100_2. The linearization circuit 400_22 may compensate for the base voltage droop of the power transistor 100_2. The linearization circuit 400_22 may couple a portion of the signal of the input RF signal RF_{IN2} and output the coupled signal to the node N3. Hereinafter, the input RF signal RF_{IN2} that is coupled by the linearization circuit 400_22 is referred to as the “coupled input RF signal RF_{IN2_COUPLED_22}”. The specific configuration and operation of the linearization circuit 400_22 will be described in more detail below.

The coupled input RF signal RF_{IN2_COUPLED_22} is input to the emitter (see FIG. 4) of the transistor QB3 of the bias circuit 200_22, which may cause the bias current I_{BIAS2_2} to increase. By increasing the bias current I_{BIAS2_2}, the base voltage droop of the power transistor 100_2 may be compensated for. That is, the linearization circuit 400_22 may compensate for the base voltage droop of the power transistor 100_2, thereby improving linearity. As described above in FIG. 1, the bias circuit 200_22 generates the bias current I_{BIAS2_1} in the second communication mode, so the linearization circuit 400_22 may also compensate for the base voltage droop of the power transistor 100_2 in the second communication mode.

On the other hand, in FIG. 5, the linearization circuit 400_1 may improve the linearity of the power transistor 100_1 regardless of the communication mode. The linearization circuit 400_21 may improve the linearity of the power transistor 100_2 in the first communication mode, and the linearization circuit 400_22 may improve the linearity of the power transistor 100_2 in the second communication mode. In other words, the linearization circuit 400_21 and the linearization circuit 400_22 may selectively improve linearity depending on the communication mode, so that each of the linearization circuit 400_21 and the linearization circuit 400_22 may be designed to be optimized depending on the communication mode. For example, since the power (for example, amplitude) of the input RF signal RF_{IN2} varies depending on the communication mode, each of the linearization circuit 400_21 and the linearization circuit 400_22 may be designed to be optimized according to the communication mode. Through this, the power amplifier 1000B, according to another embodiment, can further satisfy the linearity desired by each communication mode.

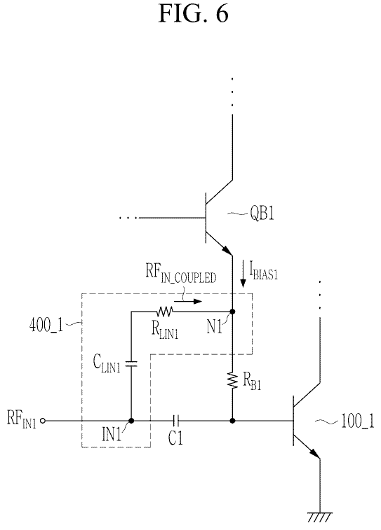

FIG. 6 is a diagram illustrating one example of the linearization circuit 400_1 of FIG. 5.

As illustrated in FIG. 6, the linearization circuit 400_1 may include a capacitor CLINT and a resistor R_{LIN1}.

One end of the capacitor C_{LIN1} may be connected to the terminal IN1, and a resistor R_{LIN1} may be connected between the other end of the capacitor C_{LIN1} and the node N1. Unlike FIG. 6, the positions of the capacitor C_{LIN1} and the resistor R_{LIN1} may be interchanged. That is, one end of the resistor R_{LIN1} is connected to the terminal IN1, and the capacitor C_{LIN1} may be connected between the other end of the resistor R_{LIN1} and the node N1.

In other words, between the terminal IN1 and the node N1, the capacitor C_{LIN1} and the resistor R_{LIN1} may be connected in series with each other. A portion of the input RF signal RF_{IN1} may be transmitted to the node N1 through the capacitor C_{LIN1} and the resistor R_{LIN1}. In other words, the linearization circuit 400_1 may output the coupled input RF signal RF_{IN1}_COUPLED to the node N1 via the capacitor CLINT and the resistor R_{LIN1}.

On the other hand, in the linearization circuit 400_1, the resistor R_{LIN1} may be omitted, and the resistor R_{LIN1} may be replaced by an inductor that serves a similar function.

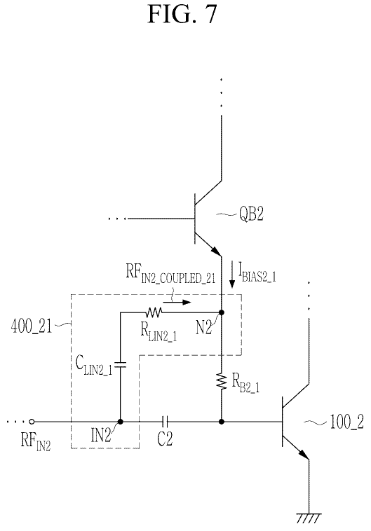

FIG. 7 is a diagram illustrating one example of the linearization circuit 400_21 of FIG. 5.

As illustrated in FIG. 7, the linearization circuit 400_21 may include a capacitor C_{LIN2_1} and a resistor R_{LIN2_1}.

One end of the capacitor C_{LIN2_1} is connected to the terminal IN2, and the resistor R_{LIN2_1} may be connected between the other end of the capacitor C_{LIN2_1} and the node N2. Unlike FIG. 7, the positions of the capacitor C_{LIN2_1} and the resistor R_{LIN2_1} may be interchanged. That is, one end of the resistor R_{LIN2_1} is connected to the terminal IN2, and the capacitor C_{LIN2_1} may be connected between the other end of the resistor R_{LIN2_1} and the node N2.

In other words, between the terminal IN2 and the node N2, the capacitor C_{LIN2_1} and the resistor R_{LIN2_1} may be connected in series with each other. A portion of the input RF signal RF_{IN2} may be transmitted to the node N2 through the capacitor C_{LIN2_1} and the resistor R_{LIN2_1}. In other words, the linearization circuit 400_21 may output the coupled input RF signal RF_{IN2}_COUPLED_21 to the node N2 via the capacitor C_{LIN2_1} and the resistor R_{LIN2_1}.

On the other hand, in the linearization circuit 400_21, the resistor R_{LIN2_1} may be omitted, and the resistor R_{LIN2_1} may be replaced by an inductor with a similar function.

As described above, the linearization circuit 400_21 may be operated in the first communication mode only to improve the linearity of the power transistor 100_2. Accordingly, the linearization circuit 400_21 of FIG. 7 may be designed to be appropriate for the first communication mode. For example, in FIG. 7, each of the capacitor C_{LIN2_1} and the resistor R_{LIN2_1} may have a design value suitable for the first communication mode.

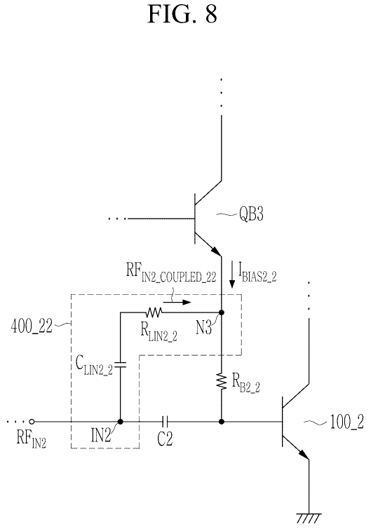

FIG. 8 is a diagram illustrating one example of the linearization circuit 400_22 of FIG. 5.

As illustrated in FIG. 8, the linearization circuit 400_22 may include a capacitor C_{LIN2_2} and a resistor R_{LIN2_2}.

One end of the capacitor C_{LIN2_2} is connected to the terminal IN2, and the resistor R_{LIN2_2} may be connected between the other end of the capacitor C_{LIN2_2} and the node N3. Unlike FIG. 8, the positions of the capacitor C_{LIN2_2} and the resistor R_{LIN2_2} may be interchanged. That is, one end of the resistor R_{LIN2_2} is connected to the terminal IN2, and the capacitor C_{LIN2_2} may be connected between the other end of the resistor R_{LIN2_2} and the node N3.

In other words, between the terminal IN2 and the node N3, the capacitor C_{LIN2_2} and the resistor R_{LIN2_2} may be connected in series with each other. A portion of the input RF signal RF_{IN2} may be transmitted to the node N3 through the capacitor C_{LIN2_2} and the resistor R_{LIN2_2}. In other words, the linearization circuit 400_22 may output the coupled input RF signal RF_{IN2}_COUPLED_22 to the node N3 via the capacitor C_{LIN2_2} and the resistor R_{LIN2_2}.

On the other hand, in the linearization circuit 400_22, the resistor R_{LIN2_2} may be omitted, and the resistor R_{LIN2_2} may be replaced by an inductor with a similar function.

As described above, the linearization circuit 400_22 may operate in the second communication mode only to improve the linearity of the power transistor 100_2. Accordingly, the linearization circuit 400_22 of FIG. 8 may be designed to be appropriate for the second communication mode. For example, in FIG. 8, each of the capacitor C_{LIN2_2} and the resistor R_{LIN2_2} may have a design value suitable for the second communication mode.

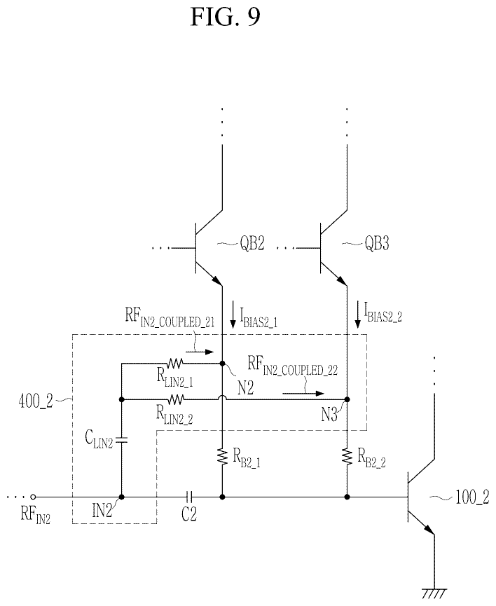

On the other hand, the capacitor C_{LIN2_1} of FIG. 7 and the capacitor C_{LIN2_2} of FIG. 8 may be integrated into one capacitor (the capacitor C_{LIN2} of FIG. 9), which is described in FIG. 9 below. That is, the linearization circuit 400_21 and the linearization circuit 400_22 may be integrated into the linearization circuit 400_2, which will be described in FIG. 9.

FIG. 9 is a diagram illustrating one example of the linearization circuit 400_2.

As illustrated in FIG. 9, the linearization circuit 400_2 may include a capacitor C_{LIN2}, a resistor R_{LIN2_1}, and a resistor R_{LIN2_2}.

One end of the capacitor C_{LIN2} is connected to the terminal IN2, and the resistor R_{LIN2_1} may be connected between the other end of the capacitor C_{LIN2} and the node N2. A portion of the input RF signal RF_{IN2} may be transmitted to the node N2 through the capacitor C_{LIN2} and the resistor R_{LIN2_1}. In the first communication mode, the linearization circuit 400_2 may output the coupled input RF signal RF_{IN2_COUPLED_21} to the node N2 via the capacitor C_{LIN2} and the resistor R_{LIN2_1}. Since the resistor R_{LIN2_1} only contributes to linearity in the first communication mode, the resistor R_{LIN2_1} may have a design value suitable for the first communication mode.

Further, the resistor R_{LIN2_2} may be connected between the other end of the capacitor C_{LIN2} and the node N3. A portion of the input RF signal RF_{IN2} may be transmitted to the node N3 through the capacitor C_{LIN2} and the resistor R_{LIN2_2}. In the second communication mode, the linearization circuit 400_2 may output the coupled input RF signal RF_{IN2_COUPLED_22} to the node N3 via the capacitor C_{LIN2} and the resistor R_{LIN2_2}. Since the resistor R_{LIN2_2} only contributes to linearity in the second communication mode, the resistor R_{LIN2_2} may have a design value suitable for the first communication mode.

The present disclosure may provide a power amplifier for simultaneously supporting various communication modes.

The present disclosure may provide a power amplifier for simultaneously supporting various communication modes and improving performance indexes.

According to at least one of the embodiments, it is possible to support various communication modes by designing a plurality of bias circuits suitable for the communication mode.

According to at least one of the embodiments, it is possible to improve performance metrics suitable for different communication modes by designing a plurality of linearization circuits suitable for communication modes.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power amplifier comprising:
a first power transistor configured to amplify a first input Radio Frequency (RF) signal, and output a first output RF signal;
a first bias circuit configured to operate in a first communication mode, and comprising a first transistor configured to supply a first bias current to the first power transistor; and
a second bias circuit configured to operate in a second communication mode, and comprising a second transistor configured to supply a second bias current to the first power transistor.

2. The power amplifier of claim 1, further comprising:
a first linearization circuit connected between a terminal to which the first input RF signal is input and the first bias circuit, and which, in the first communication mode, is configured to couple a portion of the first input RF signal to an output of the first bias circuit; and
a second linearization circuit connected between the terminal to which the first input RF signal is input and the second bias circuit, and which, in the second communication mode, is configured to couple a portion of the first input RF signal to an output of the second bias circuit.

3. The power amplifier of claim 2, wherein
the first transistor comprises a first terminal configured to supply the first bias current to the first power transistor,
the second transistor comprises a first terminal configured to supply the second bias current to the first power transistor,
the first linearization circuit configured to couple, in the first communication mode, a portion of the first input RF signal to an output of the first terminal of the first transistor, and
the second linearization circuit configured to couple, in the second communication mode, a portion of the first input RF signal to an output of the first terminal of the second transistor.

4. The power amplifier of claim 3, wherein
the first linearization circuit comprises a first capacitor connected between the terminal to which the first input RF signal is input and the first terminal of the first transistor, and
the second linearization circuit comprises a second capacitor connected between the terminal to which the first input RF signal is input and the first terminal of the second transistor.

5. The power amplifier of claim 4, wherein
the first linearization circuit further comprises a first resistor connected in series with the first capacitor between the terminal to which the first input RF signal is input and the first terminal of the first transistor, and
the second linearization circuit further comprises a second resistor connected in series with the second capacitor between the terminal to which the first input RF signal is input and the first terminal of the second transistor.

6. The power amplifier of claim 1, wherein
the first transistor comprises a first terminal configured to supply the first bias current to the first power transistor,
the second transistor comprises a first terminal configured to supply the second bias current to the first power transistor,
the power amplifier further comprises:
a first capacitor comprising a first terminal connected to a terminal to which the first input RF signal is input;
a first resistor connected between a second terminal of the first capacitor and the first terminal of the first transistor; and
a second resistor connected between the second terminal of the first capacitor and the first terminal of the second transistor.

7. The power amplifier of claim 6, wherein
the first capacitor and the first resistor are configured to couple a portion of the first input RF signal to an output of the first terminal of the first transistor in the first communication mode, and
the first capacitor and the second resistor are configured to couple a portion of the first input RF signal to an output of the first terminal of the second transistor in the second communication mode.

8. The power amplifier of claim 3, further comprising:
a first resistor connected between the first terminal of the first transistor and an input terminal of the power transistor; and
a second resistor connected between the first terminal of the second transistor and the input terminal of the power transistor.

9. The power amplifier of claim 8, wherein
the first terminal of the first transistor is an emitter of the first transistor, and
the first terminal of the second transistor is an emitter of the second transistor.

10. The power amplifier of claim 1, wherein
the first communication mode is a 2G communication mode, and
the second communication mode is a 4G communication mode or a 5G communication mode.

11. The power amplifier of claim 2, further comprising:
a second power transistor configured to amplify a second input RF signal and output a second output RF signal; and
a third bias circuit, configured to operate in the first communication mode and the second communication mode, comprising a third transistor configured to supply a third bias current to the second power transistor,
wherein the first input RF signal corresponds to the second output RF signal.

12. The power amplifier of claim 11, further comprising:
a third linearization circuit connected between a terminal to which the second input RF signal is input and the third bias circuit, and which, in the first communication mode and the second communication mode, configured to couple a portion of the second input RF signal to an output of the third bias circuit.

13. The power amplifier of claim 12, wherein
the third transistor comprises a first terminal configured to supply the third bias current to the second power transistor, and
the third linearization circuit comprises a capacitor connected between the terminal to which the second input RF signal is input and the first terminal of the third transistor.

14. The power amplifier of claim 13, wherein
the third linearization circuit further comprises a resistor connected in series with the capacitor between the terminal to which the second input RF signal is input and the first terminal of the third transistor.

15. A power amplifier comprising:
a first power transistor configured to amplify a first input Radio Frequency (RF) signal, and output a first output RF signal;
a first transistor configured to operate in a first communication mode and a second communication mode, and comprising a first terminal configured to supply a first bias current to the first power transistor;
a second power transistor configured to amplify a second input RF signal corresponding to the first output RF signal, and output a second output RF signal;
a second transistor configured to operate in the first communication mode and comprising a first terminal configured to supply a second bias current to the second power transistor; and
a third transistor configured to operate in the second communication mode and comprising a first terminal configured to supply a third bias current to the second power transistor.

16. The power amplifier of claim 15, further comprising:
a first linearization circuit connected between a terminal to which the first input RF signal is input and the first terminal of the first transistor, and configured to couple, in the first communication mode and the second communication mode, a portion of the first input RF signal to an output of the first terminal of the first transistor;
a second linearization circuit connected between a terminal to which the second input RF signal is input and the first terminal of the second transistor, and configured to couple, in the first communication mode, a portion of the second input RF signal to an output of the first terminal of the second transistor; and
a third linearization circuit connected between the terminal to which the second input RF signal is input and the first terminal of the third transistor, and configured to couple, in the second communication mode, a portion of the second input RF signal to an output of the first terminal of the third transistor.

17. The power amplifier of claim 16, wherein
the first linearization circuit comprises a first capacitor and a first resistor connected in series between the terminal to which the first input RF signal is input and the first terminal of the first transistor,
the second linearization circuit comprises a second capacitor and a second resistor connected in series between the terminal to which the second input RF signal is input and the first terminal of the second transistor, and
the third linearization circuit comprises a third capacitor and a third resistor connected in series between the terminal to which the second input RF signal is input and the first terminal of the third transistor.

18. The power amplifier of claim 15, further comprising:
a first capacitor comprising a first terminal connected to a terminal to which the second input RF signal is input;
a first resistor connected between a second terminal of the first capacitor and the first terminal of the second transistor; and
a second resistor connected between the second terminal of the first capacitor and the first terminal of the third transistor.

19. The power amplifier of claim 18, wherein
the first capacitor and the first resistor are configured to couple a portion of the second input RF signal to an output of the first terminal of the second transistor in the first communication mode, and
the first capacitor and the second resistor are configured to couple a portion of the second input RF signal to an output of the first terminal of the third transistor in the second communication mode.

20. The power amplifier of claim 15, wherein
the first terminal of the first transistor is an emitter of the first transistor, the first terminal of the second transistor is an emitter of the second transistor, and
the first terminal of the third transistor is an emitter of the third transistor.
